(19) United States
(12) Patent Application Publication
(10) Pub. No.: US 2026/0123375 A1
(43) Pub. Date: Apr. 30, 2026

(54) STRUCTURE AND FORMATION METHOD OF PACKAGE WITH THROUGH SEMICONDUCTOR VIA

(71) Applicant: Taiwan Semiconductor Manufacturing Company, Ltd., Hsinchu (TW)

(72) Inventors: Meng-Liang LIN, Hsinchu (TW); Chieh-Lung LAI, Taichung City (TW); Hsien-Wei CHEN, Hsinchu City (TW); Kathy Wei YAN, Hsinchu (TW)

(21) Appl. No.: 18/926,711

(22) Filed: Oct. 25, 2024

(51) Int. Cl. H01L 23/48; H01L 21/768; H01L 21/78; H01L 23/00; H01L 23/31; H01L 23/498; H01L 25/00; H01L 25/10; H10B 80/00

(52) U.S. Cl. CPC H10W 20/20; H10W 20/023; H10W 20/082; H10W 70/60; H10W 90/00; H10B 80/00; H10P 54/00; H10W 70/09; H10W 74/111; H10W 90/701

(57) ABSTRACT

A package structure and a formation method of a package structure are provided. The method includes forming a protective layer to laterally surround an interconnection chip. The interconnection chip has a conductive via penetrating through a semiconductor substrate of the interconnection chip. The conductive via has a first portion and a second portion, and sidewall slopes of the first portion and the second portion are different. The second portion gradually becomes narrower along a direction towards the first portion. The method also includes forming a redistribution structure over the interconnection chip and the protective layer. The redistribution structure has multiple organic layers and multiple conductive features. The method further includes bonding a first chip-containing structure and a second chip-containing structure to the redistribution structure. Each of the first chip-containing structure and the second chip-containing structure partially covers the interconnection chip.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor chips. These relatively new types of packaging technologies for semiconductor chips face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a portion of a package structure, in accordance with some embodiments.

FIGS. 2A-2J are cross-sectional views of various stages of a process for forming a portion of a package structure, in accordance with some embodiments.

FIGS. 3A-3G are cross-sectional views of various stages of a process for forming a portion of a package structure, in accordance with some embodiments.

FIGS. 4A-4C are cross-sectional views of various stages of a process for forming a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher of what is specified, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10 degrees. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x ±5 or 10%.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good chips to increase the yield and decrease costs.

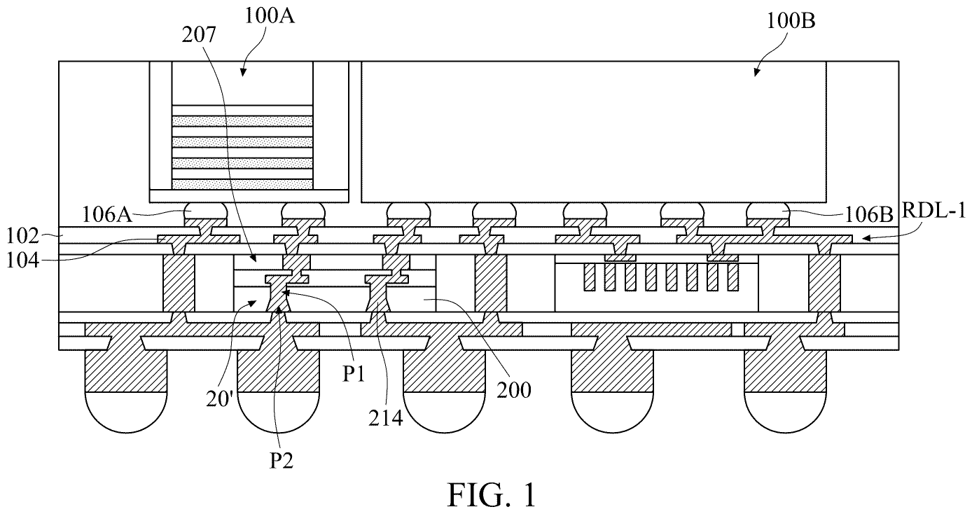

FIG. 1 is a cross-sectional view of a portion of a package structure, in accordance with some embodiments. In some embodiments, the package structure includes chip-containing structures 100A and 100B that are bonded to a redistribution structure RDL-1. The redistribution structure RDL-1 includes multiple insulating layers 102 and multiple conductive features 104. The chip-containing structures 100A and 100B may be bonded to the redistribution structure RDL-1 through conductive bumps 106A and 106B.

In some embodiments, the package structure includes an interconnection chip 20′, as shown in FIG. 1. In some embodiments, the interconnection chip 20′ is disposed on a surface of the redistribution structure RDL-1 that is opposite to the surface where the chip-containing structures 100A and 100B are bonded. Each of the chip-containing structures 100A and 100B partially covers the interconnection chip 20′. The interconnection chip 20′ extends across the adjacent edges of the chip-containing structures 100A and 100B.

In some embodiments, the interconnection chip 20′ includes a semiconductor substrate 200 and multiple conductive vias 214 that penetrate through the semiconductor substrate 200. In some embodiments, each of the conductive vias 214 has a funnel-like profile. Each of the conductive vias 214 has a first portion P1 and a second portion P2. In some embodiments, the second portion P2 gradually shrinks along a direction from the bottom of the second portion P2 towards the first portion P1.

In some embodiments, the interconnection chip 20′ includes an interconnection structure 207 that is formed over the semiconductor substrate 200 and the conductive vias 214. The interconnection structure 207 includes one or more dielectric layers and one or more conductive features. The conductive features of the interconnection structure 207 form electrical connections between the conductive vias 214 and the conductive features 104 of the redistribution structure RDL-1. In some embodiments, electrical signals are transmitted between the chip-containing structures 100A and 100B via the redistribution structure RDL-1 and the interconnection chip 20′.

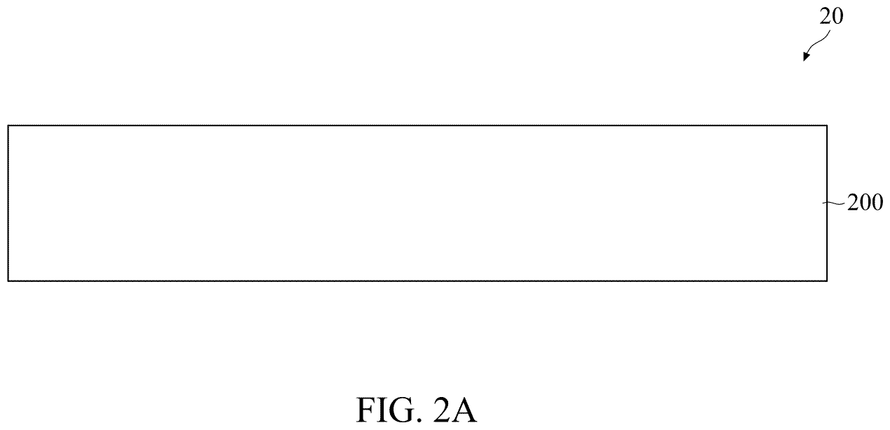

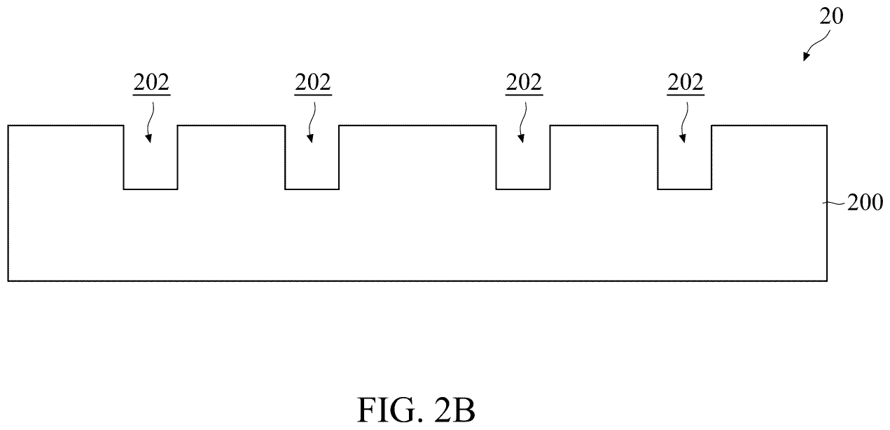

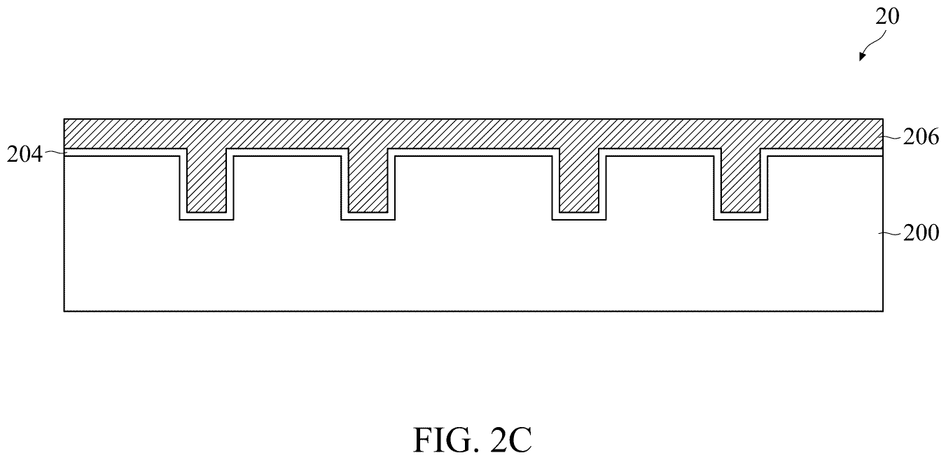

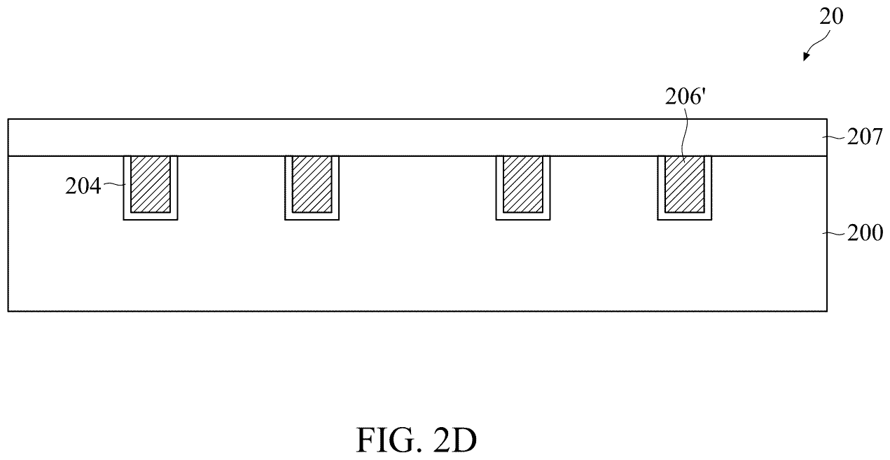

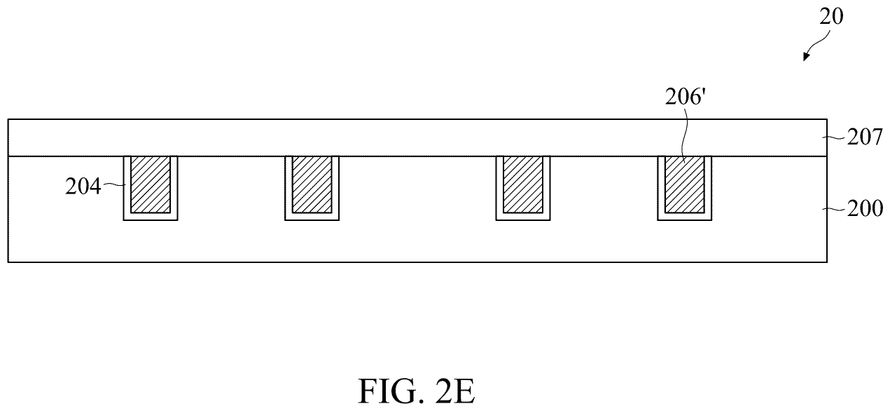

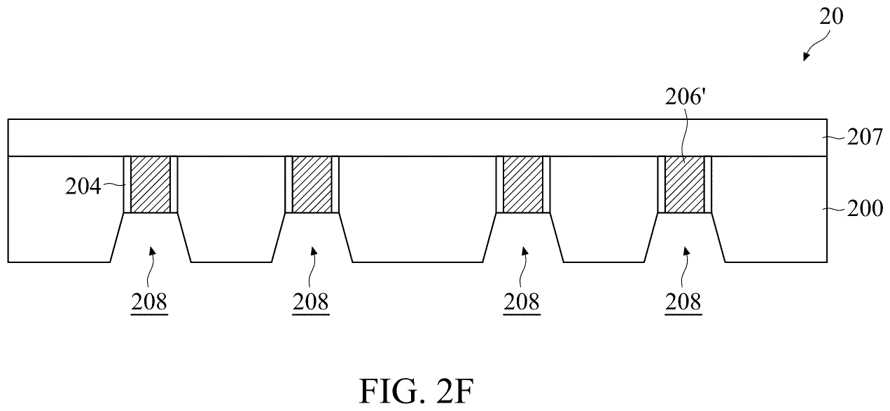

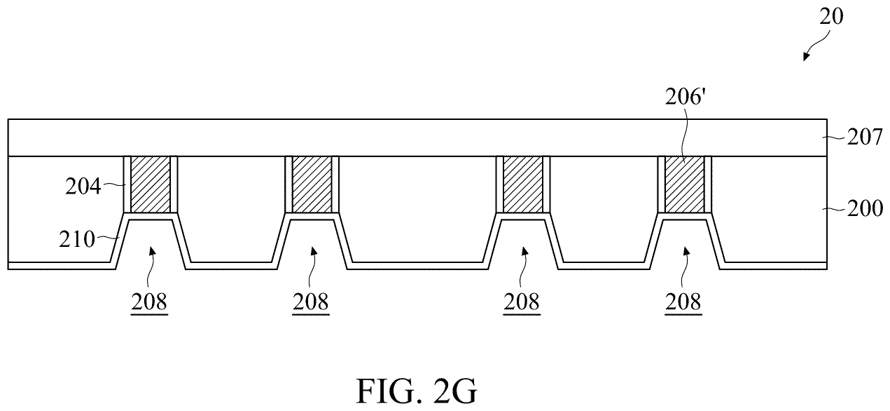

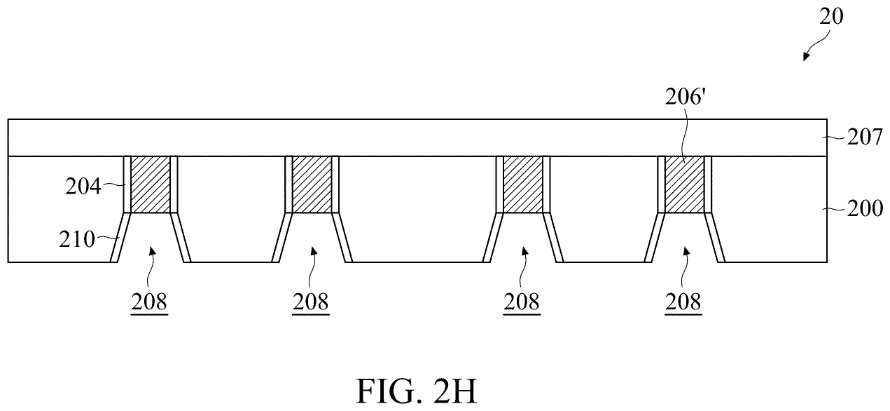

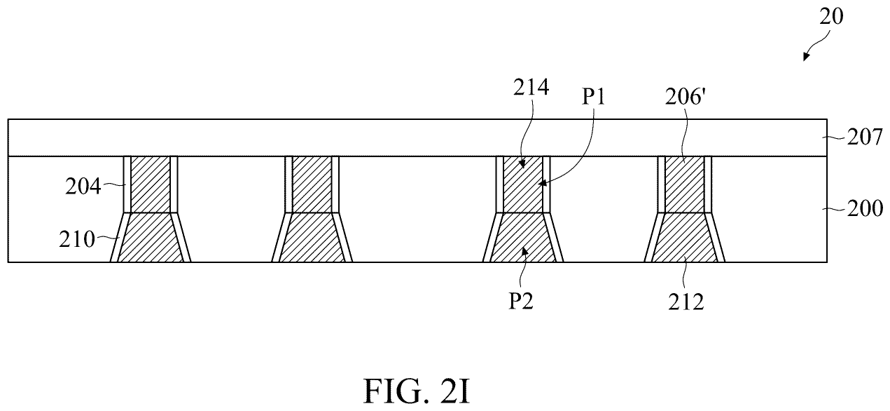

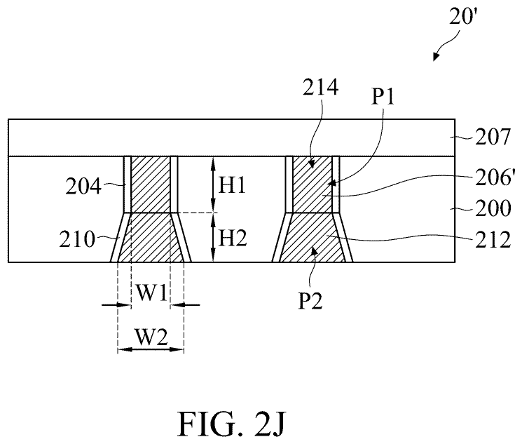

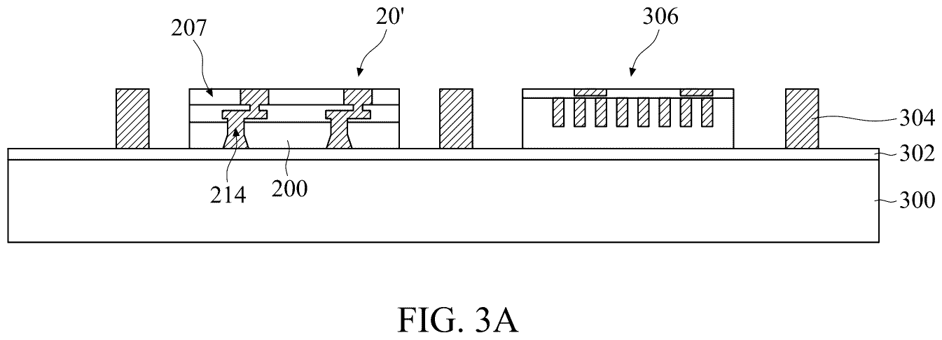

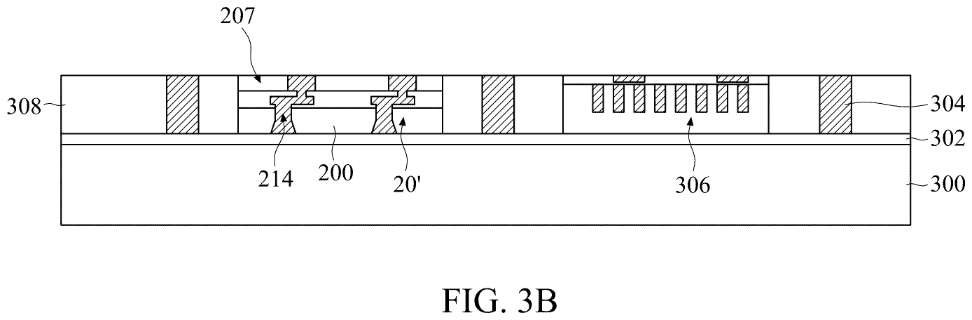

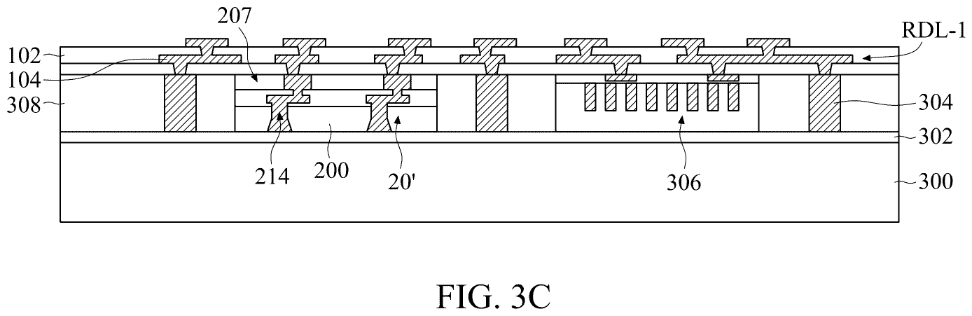

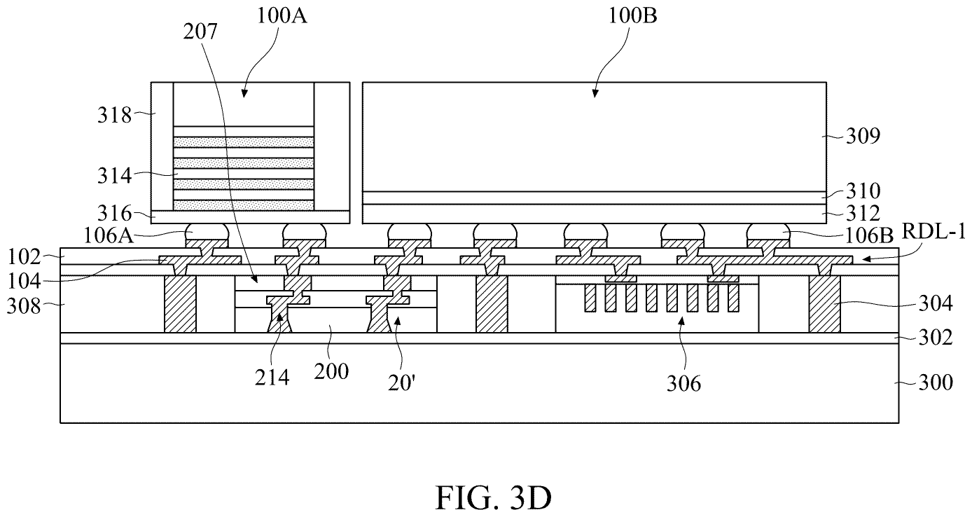

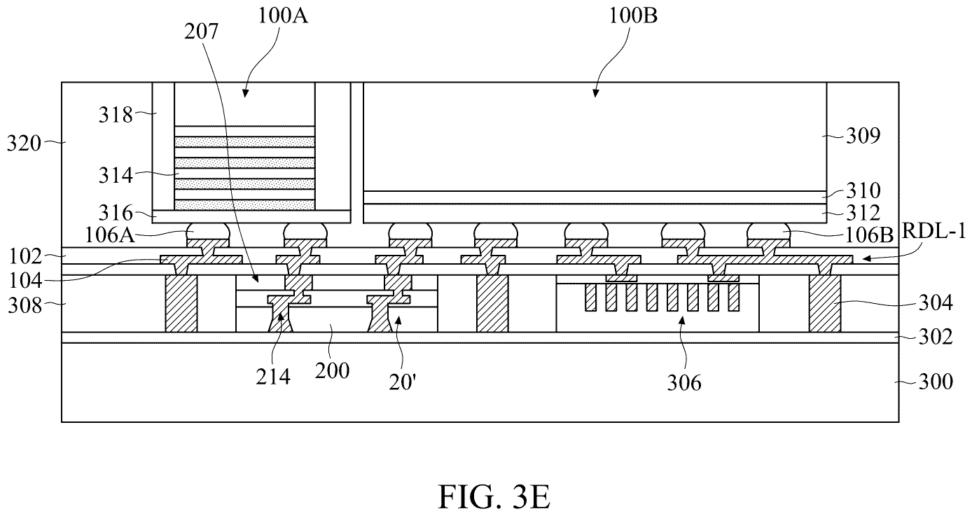

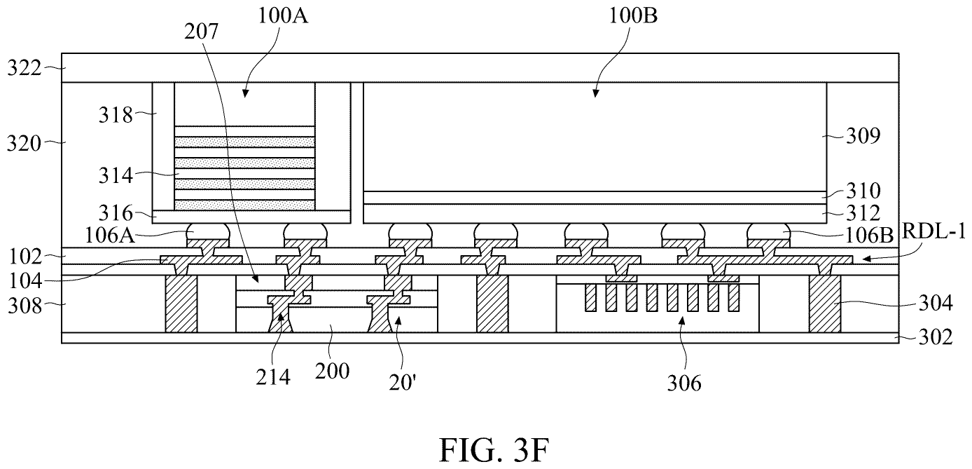

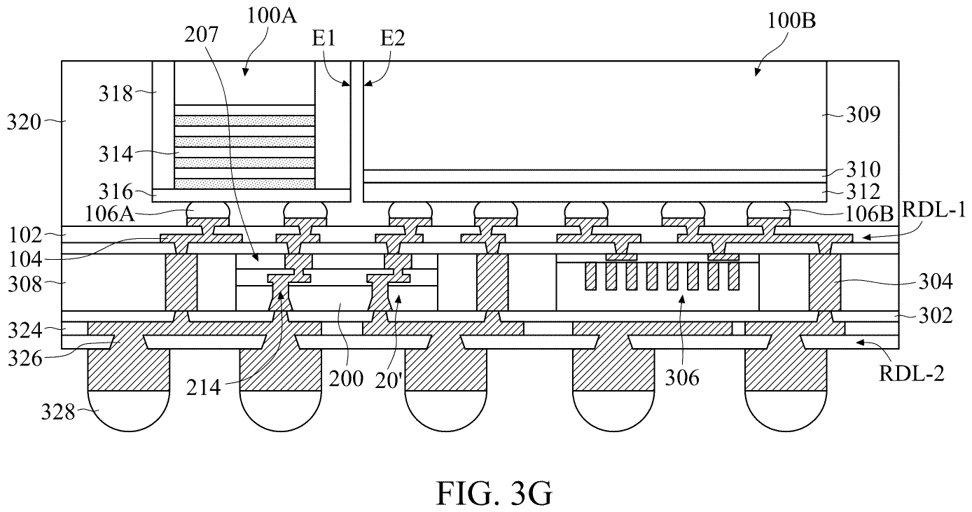

FIGS. 2A-2J are cross-sectional views of various stages of a process for forming a package structure, in accordance with some embodiments. In some embodiments, FIGS. 2A-2J illustrate the formation of the interconnection chip 20′ of the package structure shown in FIG. 1. FIGS. 3A-3G are cross-sectional views of various stages of a process for forming a package structure, in accordance with some embodiments. In some embodiments, FIGS. 3A-3G illustrate the formation of the package structure that integrates the interconnection chip 20′ and the chip-containing structures 100A and 100B.

As shown in FIG. 2A, a semiconductor wafer 20 is provided or received. The semiconductor wafer 20 includes a semiconductor substrate 200. The semiconductor substrate 200 may be made of or include silicon, germanium, silicon germanium, another suitable semiconductor material, or a combination thereof.

Afterwards, the semiconductor substrate 200 is partially removed to form multiple via holes 202, as shown in FIG. 2B in accordance with some embodiments. One or more photolithography processes and one or more etching processes may be used to form the via holes 202. In some embodiments, the via holes 202 have vertical sidewalls.

As shown in FIG. 2C, an insulating layer 204 and a conductive layer 206 are sequentially deposited, in accordance with some embodiments. The insulating layer 204 may extend along the sidewalls and bottoms of the via holes 202. The conductive layer 206 may fill the remaining space of the via holes 202.

The insulating layer 204 may be made of or include silicon oxide, silicon oxynitride, silicon nitride, carbon-containing silicon oxide, carbon-containing silicon oxynitride, carbon-containing silicon nitride, silicon carbide, one or more other suitable materials, or a combination thereof. The insulating layer 204 may be deposited using a chemical vapor deposition (CVD) process, an atomic layer deposition (ALD) process, a thermal oxidation process, one or more other applicable processes, or a combination thereof.

The conductive layer 206 may be made of or include copper, aluminum, cobalt, tungsten, gold, titanium, platinum, one or more other suitable materials, or a combination thereof. The conductive layer 206 may be deposited using a physical vapor deposition (PVD) process, a CVD process, an ALD process, an electroplating process, an electroless plating process, one or more other applicable processes, or a combination thereof.

As shown in FIG. 2D, the portions of the insulating layer 204 and the conductive layer 206 that are outside of the via holes 202 are removed, in accordance with some embodiments. As a result, the remaining portions of the conductive layer 206 form multiple conductive structures 206′, as shown in FIG. 2D. In some embodiments, each of the conductive structures 206′ forms the upper portion of a conductive via that will be formed later. The insulating layer 204 may be used to prevent short circuiting between the conductive structures 206′ and the semiconductor substrate 200 that laterally surrounds the conductive structures 206′.

A planarization process may be used to remove the portions of the insulating layer 204 and the conductive layer 206 that are outside of the via holes 202. The planarization process may include a chemical mechanical polishing (CMP) process, a grinding process, an etching process, a dry polishing process, one or more other applicable processes, or a combination thereof.

In some embodiments, other elements such as capacitor elements are formed in the semiconductor substrate 200. The capacitor elements may be deep trench capacitors. In some embodiments, the semiconductor substrate 200 is partially removed to form multiple trenches. Afterwards, a first electrode layer, a capacitor dielectric layer, and a second electrode layer are formed in the trenches. As a result, the capacitor elements are formed. The formation of the capacitor elements may involve one or more patterning processes, multiple deposition processes, and one or more planarization processes.

Afterwards, an interconnection structure 207 is formed over the semiconductor substrate 200, the insulating layer 204, and the conductive structures 206′, as shown in FIG. 2D in accordance with some embodiments. The interconnection structure 207 may include multiple dielectric layers and multiple conductive features. The conductive features may include conductive lines, conductive vias, and/or other suitable conductive structures. Some of the conductive features are electrically connected to the conductive structures 206′.

The dielectric layers of the interconnection structure 207 may be made of or include silicon oxide, silicon oxynitride, silicon nitride, carbon-containing silicon oxide, carbon-containing silicon oxynitride, carbon-containing silicon nitride, silicon carbide, one or more other suitable materials, or a combination thereof. The conductive features of the interconnection structure 207 may be made of or include copper, aluminum, cobalt, tungsten, gold, titanium, platinum, one or more other suitable materials, or a combination thereof. The formation of the interconnection structure 207 may involve multiple deposition processes, multiple patterning processes, and multiple planarization processes.

As shown in FIG. 2E, the semiconductor substrate 200 of the semiconductor wafer 20 is thinned, in accordance with some embodiments. As a result, the bottoms of the conductive structures 206′ are closer to the bottom surface of the semiconductor substrate 200, which facilitates subsequent formation of the conductive vias 214. A planarization process may be used to thin the semiconductor substrate 200. The planarization process may include a grinding process, a CMP process, a dry polishing process, one or more other applicable processes, or a combination thereof.

As shown in FIG. 2F, the semiconductor substrate 200 is partially removed from the bottom surface of the semiconductor substrate 200, in accordance with some embodiments. As a result, multiple via holes 208 are formed. One or more energy beam drilling processes may be used to form the via holes 208. The energy beam used in the energy beam drilling process may include a laser beam, an ion beam, a plasma beam, an electron beam, another suitable energy beam, or a combination thereof. In some embodiments, the via holes 208 are formed using a laser drilling process. For example, during the laser drilling process, the structure shown in FIG. 2E may be turned upside down before being irradiated with one or more laser beams.

In some embodiments, the energy beam drilling process partially removes the semiconductor substrate 200 and the insulating layer 204. As a result, the bottom surfaces of the conductive structures 206′ are exposed. The conductive structures 206′ may also be slightly removed by the energy beam drilling process. In some embodiments, the via holes 208 have inclined sidewalls. In some embodiments, each of the via holes 208 gradually shrinks along a direction towards the respective conductive structure 206′ thereabove.

As shown in FIG. 2G, an insulating layer 210 is deposited over the bottom surface of the semiconductor substrate 200 and the via holes 208, in accordance with some embodiments. The insulating layer 210 extends along the sidewalls and bottoms of the via holes 208. As a result, the conductive structures 206′ are covered by the insulating layer 210.

The insulating layer 210 may be made of or include silicon oxide, silicon oxynitride, silicon nitride, carbon-containing silicon oxide, carbon-containing silicon oxynitride, carbon-containing silicon nitride, silicon carbide, one or more other suitable materials, or a combination thereof. The insulating layer 210 may be deposited using a chemical vapor deposition (CVD) process, an atomic layer deposition (ALD) process, a thermal oxidation process, one or more other applicable processes, or a combination thereof.

As shown in FIG. 2H, the insulating layer 210 is partially removed, in accordance with some embodiments. As a result, the portions of the insulating layer 210 that cover the bottoms of the conductive structures 206′ are removed. The conductive structures 206′ are thus exposed by the via holes 208, as shown in FIG. 2H. In some embodiments, the portions of the insulating layer 210 that are originally outside of the via holes 208 and extend on the bottom surface of the semiconductor substrate 200 are also removed, as shown in FIG. 2H. One or more etching processes such as a dry etching process may be used to partially remove the insulating layer 210. The remaining portions of the insulating layer 210 extend along the sidewalls of the via holes 208. The insulating layer 210 may be used to prevent short circuiting between the semiconductor substrate 200 and the conductive structures that will be formed in the via holes 208.

As shown in FIG. 2I, multiple conductive structures 212 are formed in the via holes 208, in accordance with some embodiments. In some embodiments, a conductive material layer is deposited to overfill the via holes 208. Afterwards, a planarization process may be used to remove the portions of the conductive material layer that are outside of the via holes 208. As a result, the remaining portions of the conductive material layer form the conductive structures 212.

The conductive material layer may be made of or include copper, aluminum, cobalt, tungsten, gold, titanium, platinum, one or more other suitable materials, or a combination thereof. The conductive material layer may be deposited using a PVD process, a CVD process, an ALD process, an electroplating process, an electroless plating process, one or more other applicable processes, or a combination thereof. The planarization process may include a CMP process, a grinding process, an etching process, a dry polishing process, one or more other applicable processes, or a combination thereof.

As shown in FIG. 2I, the conductive structures 206′ and 212 together form the conductive vias 214 that penetrate through the semiconductor substrate 200, in accordance with some embodiments. The conductive vias 214 may thus function as through substrate vias (TSVs).

Each of the conductive vias 214 includes a first portion P1 and a second portion P2. In some embodiments, the first portion P1 has a substantially uniform width. In some embodiments, the first portion P1 has a substantially uniform diameter. In some embodiments, the first portion P1 has a vertical sidewall.

In some embodiments, the second portion P2 has an inclined sidewall. In some embodiments, the sidewall slopes of the first portion P1 and the second portion P2 are different from each other. In some embodiments, the first portion P1 has a greater sidewall slope than that of the second portion P2. In some embodiments, the second portion P2 gradually become narrower or gradually shrinks along a direction from the bottom of the second portion P2 towards the first portion P1 thereabove. In some embodiments, the first portion P1 and the second portion P2 are in direct contact with each other.

Afterwards, a singulation process (e.g., a sawing process or the like) is then used to cut the structure shown in FIG. 2I into multiple interconnection chips. After the sawing process, an interconnection chip 20′ of these interconnection chips is obtained, as shown in FIG. 2J in accordance with some embodiments.

As shown in FIG. 2J, the first portion P1 of the conductive via 214 (i.e., the conductive structure 206′) has a first bottom width W1, and the second portion P2 of the conductive via 214 (i.e., the conductive structure 212) has a second bottom width W2. The first bottom width W1 may be in a range from about 10 μm to about 150 μm. In some embodiments, the second bottom width W2 is wider than the first bottom width W1. In some embodiments, the ratio (W2/W1) of the second bottom width W2 to the first bottom width W1 is in a range from about 1 to about 3.

As shown in FIG. 2J, the first portion P1 (i.e., the conductive structure 206′) has a first height H1, and the second portion P2 (i.e., the conductive structure 212) has a second height H2. In some embodiments, the first height H1 is greater than the second height H2. The first height H1 may be in a range from about 50 μm to about 150 μm. The second height H2 may be in a range from about 5 μm to about 20 μm. In some embodiments, the ratio (H1/H2) of the first height H1 to the second height H2 is in a range from about 1 to about 20.

As shown in FIG. 2J, each of the conductive vias 214 has a narrower top diameter and a wider bottom diameter. In some embodiments, the narrower top diameter is substantially equal to the first bottom width W1, and the wider bottom diameter is equal to the second bottom width W2. The narrower top diameter allows for electrical connection to more compact conductive features in the interconnection structure 207 above. The wider bottom diameter helps to reduce the electrical resistance of the conductive vias 214, resulting in faster signal transmission and improved signal integrity.

The interconnection chip 20′ may be integrated into a package structure with multiple chip-containing structures. The chip-containing structures may include one or more logic control chips and one or more memory chips.

FIGS. 3A-3G are cross-sectional views of various stages of a process for forming a package structure, in accordance with some embodiments. In some embodiments, FIGS. 3A-3G illustrate the formation of the package structure that integrates the interconnection chip 20′ and the chip-containing structures 100A and 100B.

As shown in FIG. 3A, a carrier substrate 300 is provided or received, in accordance with some embodiments. The carrier substrate 300 is used as a support substrate during the fabrication process. In some embodiments, the carrier substrate 300 is a temporary support carrier and will be removed later.

The carrier substrate 300 may be made of or include a dielectric material, a semiconductor material, one or more other suitable materials, or a combination thereof. In some embodiments, the carrier substrate 300 is a dielectric substrate, such as a glass wafer. In some other embodiments, the carrier substrate 300 is a semiconductor substrate, such as a silicon wafer. The semiconductor substrate may be made of or include silicon, germanium, silicon germanium, another suitable semiconductor material, or a combination thereof.

As shown in FIG. 3A, an insulating layer 302 is then formed over the carrier substrate 300, in accordance with some embodiments. The insulating layer 302 may be made of or include one or more polymer materials. The polymer material(s) may include polybenzoxazole (PBO), polyimide (PI), epoxy-based resin, another suitable polymer material, or a combination thereof. In some embodiments, the polymer material is photosensitive. A photolithography process may therefore be used to form openings with desired patterns in the insulating layer 302. In some embodiments, a release film is formed over the carrier substrate 300 before the formation of the insulating layer 302. In some embodiments, a seed layer is formed over the insulating layer 302. The seed layer may be used to assist in a subsequent formation of conductive pillars.

Afterwards, conductive pillars 304 are formed over the carrier substrate 300, as shown in FIG. 3A in accordance with some embodiments. The conductive pillars 304 may be made of or include copper, cobalt, tungsten, aluminum, gold, another suitable material, or a combination thereof. The conductive pillars 304 may be formed using an electroplating process, an electroless plating process, a PVD process, a CVD process, another applicable process, or a combination thereof.

In some embodiments, a patterned photoresist layer is formed over the insulating layer 302. Multiple openings may be defined in the patterned photoresist layer, exposing portions of the seed layer formed over the insulating layer 302. These openings determine the shapes and positions of the conductive pillars to be formed.

Afterwards, an electroplating process or an electroless plating process may be used to deposit conductive material on the exposed portions of the seed layer to partially or completely fill the openings of the patterned photoresist layer. Then, the photoresist layer is removed, and an etching process is used to remove the portions of the seed layer that are previous covered by the patterned photoresist layer. As a result, the remaining portions of the conductive material form the conductive pillars 304.

As shown in FIG. 3A, an interconnection chip 20′ that is the same as or similar to the interconnection chip 20′ shown in FIG. 2J is disposed over the carrier substrate 300, in accordance with some embodiments. The interconnection chip 20′ may be laterally surrounded by the conductive pillars 304.

In some embodiments, one or more other device elements 306 are also disposed over the carrier substrate 300. In some embodiments, the device elements 306 may include passive devices, such as deep trench capacitors.

As shown in FIG. 3B, a protective layer 308 is formed over the carrier substrate 300, in accordance with some embodiments. The protective layer 308 laterally surrounds the conductive pillars 304, the interconnection chip 20′, and the device element 306. The protective layer 308 is made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), or a combination thereof. The conductive pillars 304 may thus be used as through molding vias (TMVs).

In some embodiments, a molding material (such as a liquid molding material) is introduced or injected to cover the conductive pillars 304, the interconnection chip 20′, and the device element 306. A thermal process is then used to cure the liquid molding material and to transform it into the protective layer 308. In some embodiments, a planarization process is performed to the protective layer 308 to provide the protective layer 308 with a planarized top surface. For example, the planarization process may include a grinding process, a CMP process, a dry polishing process, one or more other applicable processes, or a combination thereof. In some embodiments, after the planarization process, the top surfaces of the protective layer 308, the conductive pillars 304, the interconnection chip 20′, and the device element 306 are substantially level.

As shown in FIG. 3C, a redistribution structure RDL-1 is formed over the protective layer 308, the conductive pillars 304, the interconnection chip 20′, and the device element 306, in accordance with some embodiments. The redistribution structure RDL-1 may include multiple conductive features 104 that are surrounded by multiple insulating layers 102. The conductive features 104 may include multiple conductive pads that are used to receive other elements to be bonded to the redistribution structure RDL-1. The insulating layers 102 may include multiple organic layers. The organic layers are, for example, polymer-containing insulating layers. The redistribution structure RDL-1 may function as an organic redistribution interposer.

The insulating layers 102 of the redistribution structure RDL-1 may be made of or include one or more polymer materials. The polymer material(s) may include polybenzoxazole (PBO), polyimide (PI), epoxy-based resin, another suitable polymer material, or a combination thereof. In some embodiments, the polymer material is photosensitive. A photolithography process may therefore be used to form openings with desired patterns in the insulating layers. These openings may be used to contain some of the conductive features 104.

The conductive features 104 of the redistribution structure RDL-1 may include conductive lines, conductive vias, and/or conductive pads. The conductive features 104 may be made of or include copper, cobalt, tin, titanium, gold, platinum, aluminum, tungsten, one or more other suitable materials, or a combination thereof. The conductive features 104 may be formed using an electroplating process, an electroless plating process, another applicable process, or a combination thereof. The formation of the conductive features may further involve one or more etching processes and one or more planarization processes.

As shown in FIG. 3D, multiple elements including chip-containing structures 100A and 100B are disposed over the redistribution structure RDL-1, in accordance with some embodiments. Each of the chip-containing structures 100A and 100B partially covers the interconnection chip 20′ that is disposed on the opposite surface of the redistribution structure RDL-1, as shown in FIG. 3D in accordance with some embodiments. In some embodiments, before the elements are disposed, a testing operation is performed to the redistribution structure RDL-1 to ensure the quality and reliability of the redistribution structure RDL-1.

In some embodiments, the chip-containing structures 100A is bonded onto the redistribution structure RDL-1 through conductive bumps 106A, and the chip-containing structures 100B is bonded onto the redistribution structure RDL-1 through conductive bumps 106B. The conductive bumps 106A and 106B may include tin-containing solder bumps. The tin-containing solder bumps may include tin and other materials such as copper, silver, gold, aluminum, lead, another suitable material, or a combination thereof. In some embodiments, the conductive bumps 106A and 106B are lead-free solder bumps.

In some embodiments, the chip-containing structure 100A is a memory-containing structure. In some embodiments, the chip-containing structure 100A is bonded to the redistribution structure RDL-1 before the chip-containing structure 100B. In some other embodiments, the chip-containing structure 100A is bonded to the redistribution structure RDL-1 after the chip-containing structure 100B.

In some embodiments, the chip-containing structure 100A includes multiple memory chips 314 that are vertically stacked. In some embodiments, each of the memory chips 314 includes memory devices such as dynamic random access memory (DRAM) devices, static random access memory (SRAM) devices, resistive random access memory (RRAM) devices, magnetoresistive random access memory (MRAM) devices, or the like.

Multiple device elements may be formed in the device portions of the memory chips 314. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

Multiple semiconductor chips (or chiplets) such as the memory chips 314 are stacked and bonded together to form electrical connections between these semiconductor chips. In some embodiments, these memory chips 314 are stacked to form a high bandwidth memory (HBM) chip structure.

The chip-containing structure 100A further includes a protective layer 318 laterally surrounding the memory chips 314, as shown in FIG. 3D. The protective layer 318 may be made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), other suitable fillers, or a combination thereof.

In some embodiments, each of the memory chips 314 includes conductive vias, conductive bumps, and a passivation layer laterally surrounding the conductive bumps. In some embodiments, the memory chips 314 includes multiple conductive vias. The conductive vias in the memory chips 314 are used as through substrate vias (TSVs). The conductive vias may be used to form electrical connection between the memory chips 314 and a base structure 316 of the chip-containing structure 100A.

In some embodiments, the chip-containing structure 100B is a logic control chip structure that includes multiple logic control device elements. The chip-containing structure 100B may include a semiconductor substrate portion 309, a device portion 310, and an interconnection structure 312. The semiconductor substrate portion 309 may include silicon or other elementary semiconductor materials such as germanium. In some embodiments, the semiconductor substrate portion 309 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate portion 309 includes a compound semiconductor. For example, the compound semiconductor includes one or more III-V compound semiconductors having a composition defined by the formula AlX1GaX2InX3AsY1PY2NY3SbY4, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

Multiple device elements are formed in and/or on the device portion 310. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

In some embodiments, the interconnection structure 312 is formed on the device portion 310 for providing electrical connections to the device elements. The interconnection structure 312 may be a frontside interconnection structure. The interconnection structure 312 includes multiple conductive features that are surrounded by multiple dielectric layers. The conductive features may include conductive contacts, conductive lines, and conductive vias. The formation of the interconnection structure 312 may involve multiple deposition processes, multiple patterning processes, and multiple planarization processes. The device elements in the device portion 310 of the chip-containing structure 100B may be interconnected by the interconnection structure 312 to form multiple integrated circuit devices. The interconnection structure 312 includes multiple conductive features that form electrical connections to the conductive bumps 106B.

The chip-containing structure 100B may be a single semiconductor chip such as a system-on-chip (SoC) chip, system-on-integrated-chips (SoIC), and/or a package including one or more semiconductor dies that are encapsulated or protected. For the system-on-integrated-chips, multiple semiconductor dies (or chiplets) are stacked and bonded together to form electrical connections between these semiconductor dies. In some embodiments, the semiconductor dies are system-on-chip (SoC) chips that include multiple functions. In some embodiments, the back sides of the semiconductor dies face upwards with the front sides of the semiconductor dies facing the redistribution structure RDL-1.

As shown in FIG. 3E, a protective layer 320 is formed over the redistribution structure RDL-1 to laterally surround and protect the chip-containing structures 100A and 100B, in accordance with some embodiments. In some embodiments, the protective layer 320 is made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), or a combination thereof.

In some embodiments, a molding material (such as a liquid molding material) is introduced or injected to cover the redistribution structure RDL-1 and the chip-containing structures 100A and 100B. A thermal process is then used to cure the liquid molding material and to transform it into the protective layer 320. In some embodiments, a planarization process is performed to the protective layer 320. For example, the planarization process may include a grinding process, a CMP process, a dry polishing process, one or more other applicable processes, or a combination thereof.

As shown in FIG. 3F, the carrier substrate 300 is removed, in accordance with some embodiments. In some embodiments, before the removal of the carrier substrate 300, a carrier 322 is attached, as shown in FIG. 3F. The carrier 322 may be a carrier tape. The carrier 322 may assist in the subsequent formation processes.

As shown in FIG. 3G, a backside redistribution structure RDL-2 is formed, in accordance with some embodiments. The backside redistribution structure RDL-2 may include the previously formed insulating layer 302, multiple insulating layers 324, and multiple conductive features 326. Electrical connections to the conductive pillars 304, the interconnection chip 20′, and the redistribution structure RDL-1 are established through the conductive features 326. The conductive features 136 also include conductive pads that are used to receive conductive bumps that will be formed later.

Afterwards, conductive bumps 328 are formed, as shown in FIG. 3G in accordance with some embodiments. In some embodiments, the conductive bumps 328 are tin-containing solder bumps. The tin-containing solder bumps may further include copper, silver, gold, aluminum, lead, one or more other suitable materials, or a combination thereof. In some other embodiments, the tin-containing solder bumps are lead-free.

In some embodiments, each of the conductive bumps 328 is wider than each of the conductive bumps 106A and 106B. In some embodiments, each of the conductive bumps 328 is larger than each of the conductive bumps 106A and 106B. In some embodiments, the pitch between the conductive bumps 328 is wider than the pitch between the conductive bumps 106A or 106B.

Afterwards, a singulation process (e.g., sawing or the like) is then used to cut through the structure into multiple separate package structures. After the sawing process, the carrier 322 may be removed. One of the package structures is shown in FIG. 3G. The package structure shown in FIG. 3G may then be bonded to a package substrate through the conductive bumps 328. The package substrate may be a circuit substrate.

In some embodiments, the side edges of the protective layers 320 and 308 and the redistribution structures RDL-1 and RDL-2 are vertically aligned. In some embodiments, the side edges of the protective layers 320 and 308 and the redistribution structures RDL-1 and RDL-2 together form a vertical sidewall.

In some embodiments, the interface between the first portion P1 and the second portion P2 is a substantially planar surface. However, embodiments of the disclosure are not limited thereto. Many variations and/or modifications can be made to embodiments of the disclosure. In some other embodiments, the interface between the first portion P1 and the second portion P2 is a curved surface.

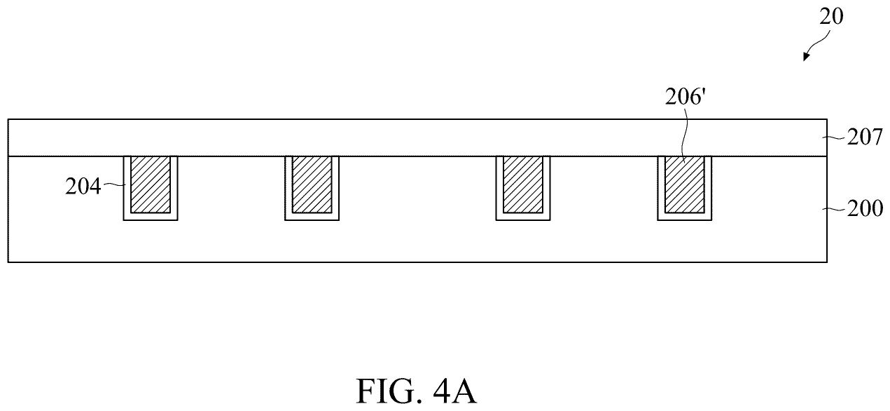

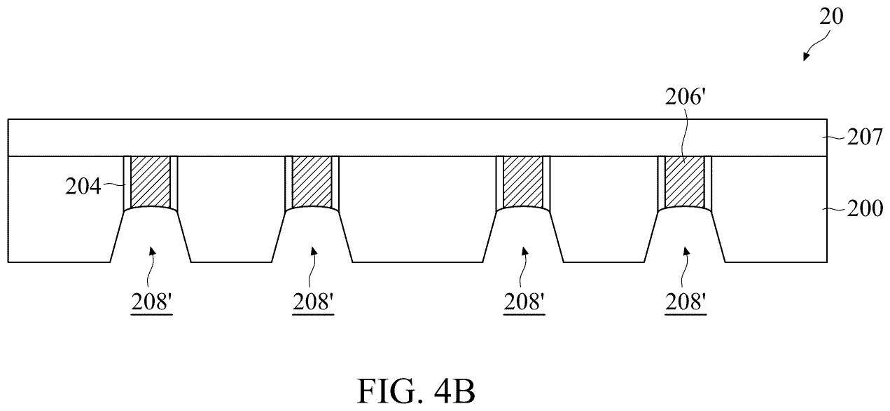

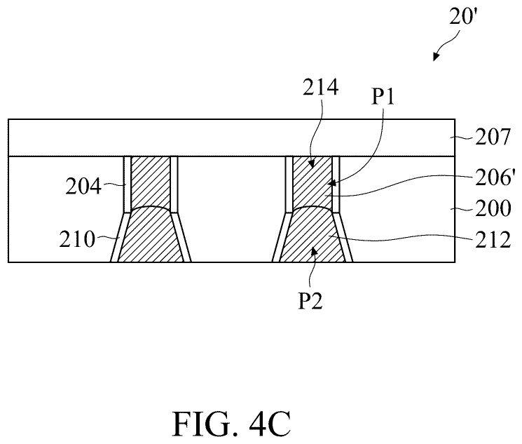

FIGS. 4A-4C are cross-sectional views of various stages of a process for forming a portion of a package structure, in accordance with some embodiments. As shown in FIG. 4A, a structure that is the same as or similar to the structure shown in FIG. 2E is formed.

Afterwards, similar to the embodiments illustrated in FIG. 2F, an energy beam drilling process is used to partially remove the semiconductor substrate 200, as shown in FIG. 4B in accordance with some embodiments. As a result, multiple via holes 208′ are formed. In some embodiments, lower portions of the conductive structures 206′ are also partially removed by the energy beam drilling process. As a result, the bottoms of conductive structures 206′ are curved.

Afterwards, the processes that are the same as or similar to those shown in FIGS. 2G-2J are performed. As a result, the interconnection chip 20′ shown in FIG. 4C is formed, in accordance with some embodiments. In some embodiments, the second portion P2 extends into the first portion P1, as shown in FIG. 4C. In some embodiments, the interface between the first portion P1 and the second portion P2 is a curved surface. In some embodiments, the top end of the second portion P2 is vertically between the opposite ends of the first portion P1. The interconnection chip 20′ shown in FIG. 4C may also be used in the package structure shown in FIGS. 1 and/or 3G.

This disclosure presents a package structure featuring an interconnection chip with through-substrate vias. The interconnection chip spans across opposite edges of adjacent chip-containing structures, enhancing communication between them. Each through-substrate via has a narrower end connected to a redistribution structure with finer conductive features, and a wider end connected to a structure with broader conductive features. The narrower end facilitates connections to more compact conductive features, while the wider end reduces electrical resistance, leading to faster signal transmission and improved signal integrity. Consequently, the performance and reliability of the package structure are significantly enhanced.

In accordance with some embodiments, a method for forming a package structure is provided. The method includes forming a protective layer to laterally surround an interconnection chip. The interconnection chip has a conductive via penetrating through a semiconductor substrate of the interconnection chip. The conductive via has a first portion and a second portion, and sidewall slopes of the first portion and the second portion are different. The second portion gradually becomes narrower along a direction towards the first portion. The method also includes forming a redistribution structure over the interconnection chip and the protective layer. The redistribution structure has multiple organic layers and multiple conductive features. The method further includes bonding a first chip-containing structure and a second chip-containing structure to the redistribution structure. Each of the first chip-containing structure and the second chip-containing structure partially covers the interconnection chip.

In accordance with some embodiments, a method for forming a package structure is provided. The method includes disposing an interconnection chip over a carrier substrate. The interconnection chip has a conductive via penetrating through a semiconductor substrate of the interconnection chip. The conductive via has a first portion and a second portion. The second portion gradually shrinks along a direction towards the first portion, and the first portion has a greater sidewall slope than that of the second portion. The method also includes forming a first protective layer over the carrier substrate to laterally surround the interconnection chip and forming a redistribution structure over the interconnection chip and the protective layer. The method further includes bonding a memory-containing structure and a chip-containing structure to the redistribution structure. The interconnection chip extends across a gap between the memory-containing structure and the chip-containing structure. In addition, the method includes forming a second protective layer laterally surrounding the memory-containing structure and the chip-containing structure.

In accordance with some embodiments, a package structure is provided. The package structure includes a redistribution structure having multiple organic layers. The package structure also includes a first chip-containing structure and a second chip-containing structure, each bonded to the redistribution structure. The package structure further includes an interconnection chip extending across a first edge of the first chip-containing structure and a second edge of the second chip-containing structure. The interconnection chip has a conductive via penetrating through a semiconductor substrate of the interconnection chip. The conductive via has a first portion and a second portion, and the first portion is between the second portion and the redistribution structure. Sidewall slopes of the first portion and the second portion are different, and the second portion gradually becomes narrower along a direction towards the first portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
forming a protective layer to laterally surround an interconnection chip, wherein the interconnection chip has a conductive via penetrating through a semiconductor substrate of the interconnection chip, the conductive via has a first portion and a second portion, sidewall slopes of the first portion and the second portion are different, and the second portion gradually becomes narrower along a direction towards the first portion;
forming a redistribution structure over the interconnection chip and the protective layer, wherein the redistribution structure has a plurality of organic layers and a plurality of conductive features; and
bonding a first chip-containing structure and a second chip-containing structure to the redistribution structure, wherein each of the first chip-containing structure and the second chip-containing structure partially covers the interconnection chip.

2. The method for forming a package structure as claimed in claim 1, further comprising:
forming a conductive pillar beside the interconnection chip before the protective layer is formed.

3. The method for forming a package structure as claimed in claim 2, further comprising:
a second redistribution structure extending across opposite edges of the conductive pillar and the interconnection chip after the first chip-containing structure and the second chip-containing structure are bonded to the redistribution structure, wherein the protective layer is between the redistribution structure and the second redistribution structure.

4. The method for forming a package structure as claimed in claim 1, wherein the first portion has a first bottom width, the second portion has a second bottom width, the second bottom width is wider than the first bottom width, and a ratio of the second bottom width to the first bottom width is in a range from about 1 to about 3.

5. The method for forming a package structure as claimed in claim 1, wherein the first portion has a first height, the second portion has a second height, the first height is greater than the second height, and a ratio of the first height to the second height is in a range from about 1 to about 20.

6. The method for forming a package structure as claimed in claim 1, wherein a topmost surface of the second portion is vertically between a topmost surface of the first portion and a bottommost surface of the first portion.

7. The method for forming a package structure as claimed in claim 1, further comprising:
forming an upper via hole in a semiconductor wafer;
forming a first insulating layer extending along a sidewall and a bottom of the upper via hole;
forming a first conductive structure in the upper via hole after the first insulating layer is formed;
forming a frontside interconnection structure over the semiconductor wafer and the first conductive structure;
forming a lower via hole in the semiconductor wafer, wherein the lower via hole exposes bottom surfaces of the first insulating layer and the first conductive structure;
forming a second insulating layer extending along a sidewall of the lower via hole; and
forming a second conductive structure in the lower via hole after the second insulating layer is formed, wherein the first conductive structure and the second conductive structure together form the conductive via of the interconnection chip.

8. The method for forming a package structure as claimed in claim 7, further comprising:
sawing the semiconductor wafer, wherein a remaining portion of the semiconductor wafer forms the interconnection chip.

9. The method for forming a package structure as claimed in claim 7, further comprising:
thinning the semiconductor wafer after the formation of the frontside interconnection structure and before the formation of the lower via hole.

10. The method for forming a package structure as claimed in claim 7, wherein the lower via hole is formed by a laser drilling process.

11. A method for forming a package structure, comprising:
disposing an interconnection chip over a carrier substrate, wherein the interconnection chip has a conductive via penetrating through a semiconductor substrate of the interconnection chip, the conductive via has a first portion and a second portion, the second portion gradually shrinks along a direction towards the first portion, and the first portion has a greater sidewall slope than that of the second portion;
forming a first protective layer over the carrier substrate to laterally surround the interconnection chip;
forming a redistribution structure over the interconnection chip and the protective layer;
bonding a memory-containing structure and a chip-containing structure to the redistribution structure, wherein the interconnection chip extends across a gap between the memory-containing structure and the chip-containing structure; and
forming a second protective layer laterally surrounding the memory-containing structure and the chip-containing structure.

12. The method for forming a package structure as claimed in claim 11, further comprising:
removing the carrier substrate after the second protective layer is formed; and
forming a second redistribution structure extending across opposite edges of the memory-containing structure, the interconnection chip, and the chip-containing structure, wherein the second protective layer is between the second redistribution structure and the redistribution structure.

13. The method for forming a package structure as claimed in claim 11, further comprising:
forming a conductive pillar over the carrier substrate before the first protective layer is formed, wherein the conductive pillar is electrically connected to conductive features of the redistribution structure and the second redistribution structure.

14. The method for forming a package structure as claimed in claim 11, further comprising:
forming an upper via hole in a substrate;
forming a first conductive structure in the upper via hole;
forming a lower via hole in the substrate, wherein the lower via hole exposes a bottom surface of the first conductive structure;
forming a second conductive structure in the lower via hole, wherein the first conductive structure and the second conductive structure together form the conductive via of the interconnection chip; and
sawing the substrate to obtain the interconnection chip.

15. The method for forming a package structure as claimed in claim 14, wherein the formation of the lower via hole comprises partially removing the substrate and the first conductive structure using an energy beam drilling process.

16. A package structure, comprising:
a redistribution structure having a plurality of organic layers;
a first chip-containing structure and a second chip-containing structure, each bonded to the redistribution structure; and
an interconnection chip extending across a first edge of the first chip-containing structure and a second edge of the second chip-containing structure, wherein the interconnection chip has a conductive via penetrating through a semiconductor substrate of the interconnection chip, the conductive via has a first portion and a second portion, the first portion is between the second portion and the redistribution structure, sidewall slopes of the first portion and the second portion are different, and the second portion gradually becomes narrower along a direction towards the first portion.

17. The package structure as claimed in claim 16, wherein the first portion has a vertical sidewall.

18. The package structure as claimed in claim 16, wherein the first portion has a first bottom width, the second portion has a second bottom width, the second bottom width is wider than the first bottom width, and a ratio of the second bottom width to the first bottom width is in a range from about 1 to about 3.

19. The package structure as claimed in claim 16, wherein the first portion has a first height, the second portion has a second height, the first height is greater than the second height, and a ratio of the first height to the second height is in a range from about 1 to about 20.

20. The package structure as claimed in claim 16, wherein a topmost surface of the second portion is vertically between a topmost surface of the first portion and a bottommost surface of the first portion.
